(19) United States
(12) Patent Application Publication
(10) Pub. No.: US 2020/0135703 A1
(43) Pub. Date: Apr. 30, 2020

(54) LIGHT FIELD DISPLAY FOR HEAD MOUNTED APPARATUS USING METAPIXELS

(71) Applicant: Intel Corporation, Santa Clara, CA (US)

(72) Inventors: Khaled AHMED, Anaheim, CA (US); Richmond HICKS, Aloha, OR (US); Seth HUNTER, Santa Clara, CA (US); Alexey SUPIKOV, San Jose, CA (US); Jun JIANG, Portland, OR (US)

(21) Appl. No.: 16/176,605

(22) Filed: Oct. 31, 2018

(51) Int. Cl. H01L 25/075; G02B 27/22; H01L 33/58

(52) U.S. Cl. CPC H01L 25/0753; H01L 33/58; G02B 27/22

(57) ABSTRACT

Embodiments disclosed herein include 3D displays with meta-surfaces and methods of forming such displays. In an embodiment, a display may comprise a display backplane substrate, and a light emission source on the display backplane substrate. In an embodiment, a meta-surface may be formed over the light emission source. In an embodiment, the meta-surface comprises a plurality of nano-features for modifying a path of light emitted by the light emission source.

### TECHNICAL FIELD

Embodiments of the disclosure are in the field of three-dimensional (3D) displays.

### BACKGROUND

Despite the increased demand for virtual reality systems, the technology is still bulky and does not provide correct focus cues to the visual system. Currently available head-mounted displays generally rely on stereoscopic displays. Stereoscopic displays create 3D images by showing the left eye and right eye images that are slightly offset—the more offset, the closer an object appears. An example of a stereoscopic display is shown in FIG. 1.

In FIG. 1, a virtual image 125 is generated by the display 120 by delivering a first image 102L to the left eye 105L and a second image 1028 to the right eye 105R. In such systems, the eyes are accommodating a screen that is 40 mm to 60 mm from the eyes 105 (i.e., the accommodation distance) while at the same time converging to a virtual plane of the virtual image 125 that is much further away (i.e., the convergence distance). This phenomena is called the “vergence-accommodation conflict” or convergence-accommodation mismatch. The vergence-accommodation conflict may cause eye fatigue and discomfort. In some users, the vergence-accommodation conflict may also contribute to virtual reality sickness.

### BRIEF DESCRIPTION OF THE DRAWINGS

FIG. 1 is a schematic illustration of a stereoscopic three-dimension (3D) display.

FIG. 2 is a perspective view illustration of a display with subpixels that generate a multi-view light field, in accordance with an embodiment.

FIG. 3A is a perspective view illustration of a subpixel with a meta-surface that provides a single view light field, in accordance with an embodiment.

FIG. 3B is a perspective view illustration of a subpixel with a meta-surface that has a plurality of regions that generates a multi-view light field, in accordance with an embodiment.

FIG. 4 is a schematic illustration of a display that provides three light field views to an eye, in accordance with an embodiment.

FIGS. 5A-5C are cross-sectional illustrations that depict a method of forming a display with a meta-surface over each subpixel, in accordance with an embodiment.

FIGS. 6A-6C are perspective view illustrations of nano-features that may be used to form meta-surfaces, in accordance with an embodiment.

FIGS. 6D-6I are perspective view and cross-sectional illustrations of nano-features that comprise a core and a coating, in accordance with an embodiment.

FIG. 7 is a perspective illustration of an exemplary meta-surface, in accordance with an embodiment.

FIG. 8 is a cross-sectional illustration of a display with meta-surfaces that are also color conversion devices, in accordance with an embodiment.

FIG. 9A is a plan view illustration of a display with pixels that have more green subpixels than red subpixels or blue subpixels, in accordance with an embodiment.

FIG. 9B is a cross-sectional illustration of the display in FIG. 9A that illustrates the meta-surfaces, in accordance with an embodiment.

FIG. 10A is a schematic of a display with lenses where light from the edge pixels is projected outside of an eye-box.

FIG. 10B is a schematic of a display with meta-surfaces that direct light from the edge of the display into the eye-box, in accordance with an embodiment.

FIG. 11A is a schematic of a head mounted display with a wired connection to a computing system, in accordance with an embodiment.

FIG. 11B is a schematic of a head mounted display with an integrated computing system, in accordance with an embodiment.

FIG. 12 is an electronic device having a display, in accordance with embodiments of the present disclosure.

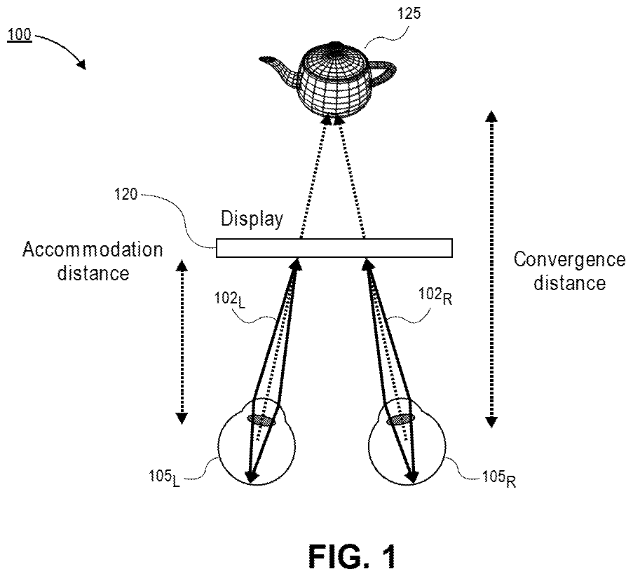

### DESCRIPTION OF THE EMBODIMENTS

A display for providing multi-view light fields and methods of fabricating such displays are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As noted above, the vergence-accommodation conflict currently results in discomfort when viewing stereoscopic 3D images. Accordingly, embodiments disclosed herein include a display that generates 3D images through the use of light fields. Instead of flat images, light fields that mimic the angles of light that bounce off objects in the real world are used. Such light field images have been shown to minimize or eliminate the vergence-accommodation conflict.

In 3D displays, the intensity and color of light and the direction of the light rays need to be reproduced. The term “light field” is used herein to refer to the field of light either represented by a set of light rays or a wavefront (holography). Ideally, a perfect 3D display would reproduce a set of all the light rays (or light field) from a 3D scene. Although standard holography can perform this task well, the recording of a holographic medium is too slow to permit real-time operation. Auto-stereoscopic multi-view 3D displays can be realized using pure geometrical optics techniques, such as multi-projector, parallax barrier, integral imaging, or a combination of these. Multi-projector solutions have been demonstrated, but they are difficult to implement on a virtual reality device. Near-eye light field displays with microlens optical designs have also been demonstrated. However, the resolution tradeoff is directly proportional to the number of angular views provided. Additionally, some of the views are subject to absorption, scattering, and aberrations—particularly in the boundaries between the lenses.

Accordingly, embodiments disclosed herein include displays that comprise meta-surfaces over the subpixels for steering the emitted light instead of optical lenses. The small size of features (e.g., sub-wavelength) on the meta-surfaces allow for unique subpixel arrangements of different sizes and spacing, where each subpixel has its own angular meta-surface. The use of on-subpixel-meta-surfaces to control viewpoints in a light field display offers unique trade-offs between spatial resolution and viewpoints. For example, the number of views for green subpixels (i.e., luminance information) may be greater than the number of views for red and blue subpixels (i.e., chrominance information). Additionally, viewpoints may be tuned to expected eye-box locations in order to improve perceived resolution.

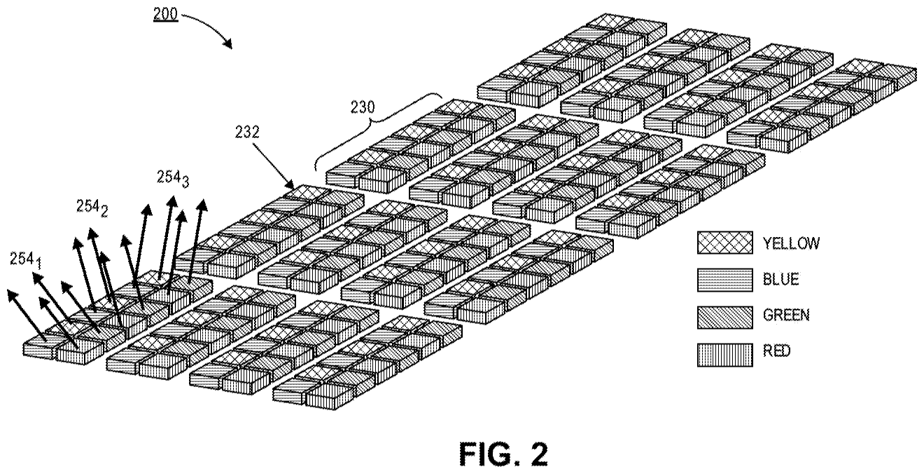

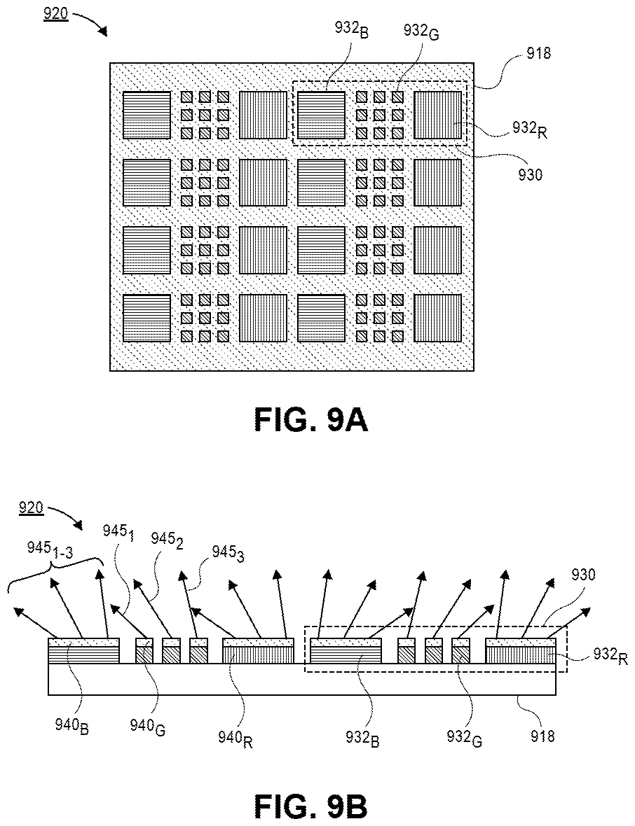

Referring now to FIG. 2, a schematic illustration of a display 200 is shown, in accordance with an embodiment. In an embodiment, the display 200 may comprise a plurality of pixels 230. The pixels 230 include subpixels 232. In the illustrated embodiment, each pixel 230 includes twelve subpixels 232 (e.g., three each of red subpixels 232, green subpixels 232, blue subpixels 232, and yellow subpixels 232). However, it is to be appreciated that any number of subpixels 232, any arrangement of subpixels 232, and/or any color combinations may be chosen for the pixels 230. Alternative subpixel configurations are described in greater detail below with respect to FIGS. 9A and 9B.

In an embodiment, each subpixel 232 may comprise a meta-surface that modifies the path of light 254 emitted by the respective subpixel 232. For clarity, the meta-surfaces are not depicted in FIG. 2. The meta-surfaces may be chosen to direct light at a chosen angle in order to generate a light field that is used to generate a 3D image. In an embodiment, each pixel 230 may comprise a plurality of views represented by light paths 254 of different angles. For example, a first view is provided by the light path 254₁, a second view is provided by the light path 254₂, and a third view is provided by path 254₃.

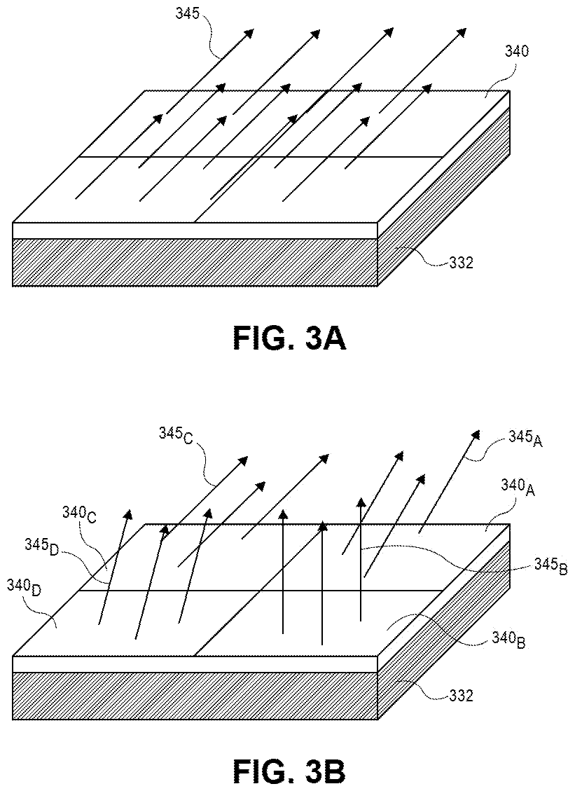

Referring now to FIG. 3A, a perspective view of a subpixel 332 is shown, in accordance with an embodiment. In an embodiment, a meta-surface 340 may be positioned over the surface of the subpixel 332. In the illustrated embodiment, the meta-surface 340 is directly over a top surface of the subpixel 332. However, in some embodiments, one or more layers (e.g., transparent conductors or dielectrics) may be formed between the subpixel 332 and the meta-surface 340.

In an embodiment, the meta-surface 340 is a material layer that is fabricated with features that are smaller than the wavelength of the light emitted by the subpixel 332. The features of the meta-surface 340 modify the path of the light 345 in a predictable manner. The meta-surface 340 is described in greater detail below. In FIG. 3A the entire meta-surface 340 provides a uniform modification of the path of the light 345. That is, the angle of the emitted light 345 is uniform across the meta-surface 340. However, embodiments are not limited to such configurations, and the meta-surface 340 may include a non-uniform meta-surface 340.

An example of an embodiment with a non-uniform meta-surface 340 is shown in FIG. 3B. As shown, a plurality of meta-surface regions 340A-340D may be formed over a single subpixel 332. Each of the meta-surface regions 340A-340D may provide different angles to the emitted light 345. As shown, emitted light 345A in meta-surface region 340A has a first angle, emitted light 345B in meta-surface region 340B has a second angle, emitted light 345c in meta-surface region 340c has a third angle, and emitted light 345D in meta-surface region 340D has a fourth angle. Accordingly, a plurality of views may be obtained from a single subpixel 332.

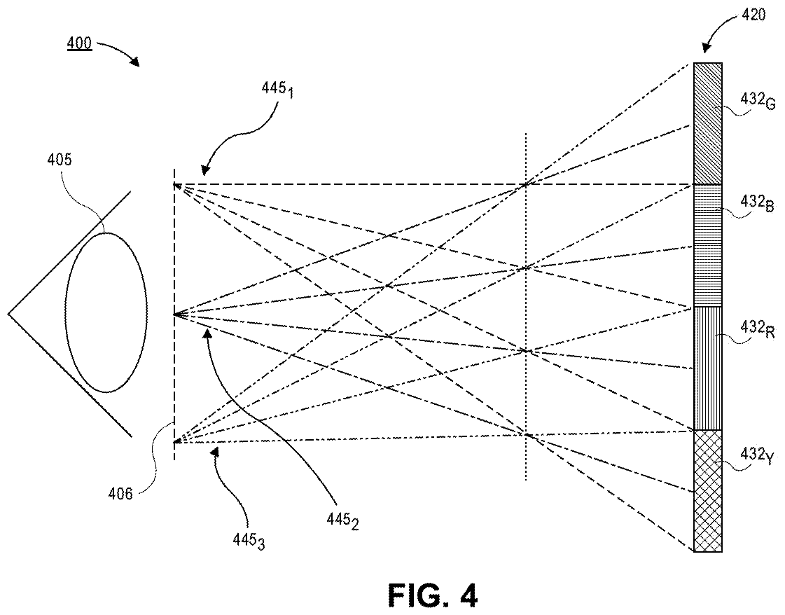

Referring now to FIG. 4, a schematic of a display system 400 with a display 420 emitting light towards an eye-box 406 in front of a user's pupil 405 is shown, in accordance with an embodiment. As shown, a single pixel (e.g., comprising subpixels 432_{G}, 432_{B}, 432_{R}, and 432_{Y}) is capable of providing a plurality of views 445₁-445₃. For example, each subpixel 432 may emit light 445₁₋₃ that contributes to the one of the three views seen by the pupil 405. While not shown in FIG. 4, it is to be appreciated that a meta-surface may be formed over each of the subpixels 432 in order to modify the light 445 to provide the three different views.

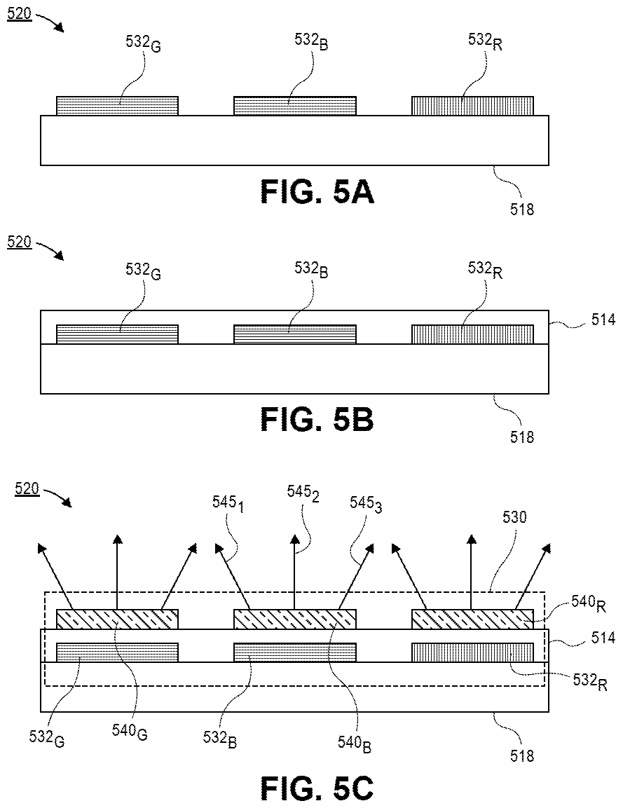

Referring now to FIGS. 5A-5C, a series of cross-sectional illustrations depict a method of forming a meta-surface over subpixels, in accordance with an embodiment.

In FIG. 5A, a cross-sectional illustration of a display 520 with a display backplane 518 that comprises a green subpixel 532_{G}, a blue subpixel 532_{B}, and a red subpixel 532_{R} is shown, in accordance with an embodiment. While illustrated schematically as a solid block, it is to be appreciated that the display backplane 518 may comprise a substrate (e.g., a glass substrate) with circuitry (e.g., thin film transistors) and data driver and scan driver chips for controlling pixel circuits. The display backplane 518 may also comprise one or more dielectric layers to isolate components, as is known to those skilled in the art.

In an embodiment, the subpixels 532 on the display backplane 518 may be any suitable light emitting device. In a particular embodiment, the subpixels 532 may be micro light emitting diode (LED) devices. For example, the subpixels 532 may be formed on one or more source wafers (e.g., silicon wafers) and transferred to the display backplane 518 with a pick-and-place process, or a direct transfer from the source wafer to the display backplane 518. While explicitly disclosing micro LED devices, it is to be appreciated that other light emitting devices, such as organic LEDs (OLEDs) may also be used in accordance with embodiments described herein.

Referring now to FIG. 5B, a cross-sectional illustration after a transparent dielectric layer 514 is formed over the subpixels 532 is shown, in accordance with an embodiment. In an embodiment, the transparent dielectric layer 514 may be titanium oxide (TiO₂), hafnium oxide (HfO₂), zirconium oxide (ZrO₂) or the like. The transparent dielectric layer 514 may have a refractive index that is lower than the refractive index of semiconductor material of the subpixels 532 and serve as an index matching layer that reduces total internal reflections of light emitted by the subpixels 532.

Referring now to FIG. 5C, a cross-sectional illustration after the meta-surfaces 540 are positioned over the subpixels 532 is shown, in accordance with an embodiment. In an embodiment, a first meta-surface 540_{G} may be positioned over the first subpixel 532_{G}, a second meta-surface 540_{B} may be positioned over the second subpixel 532_{B}, and a third meta-surface 540_{R} may be positioned over the third subpixel 532_{R} in order to form a pixel 530. In FIG. 5C, the pixel 530 is shown with three different colors (e.g., the first subpixel 532_{G} is green, the second subpixel 532_{B} is blue, and the third subpixel 532_{R} is red). However, it is to be appreciated that the pixel 530 may be formed with any combination of colors, and any number of each color. Furthermore, while the cross-sectional illustration depicts the three subpixels in a row, other embodiments may include subpixels arranged in a 2×2, 3×3, etc. configuration.

In an embodiment, each meta-surface 540 may modify the light 545 emitted by the underlying subpixel 532. For example, each meta-surface 540 may provide a uniform modification of the light 545 (i.e., similar to what is shown in FIG. 3A) in order to provide a single view, or each meta-surface 540 may provide a plurality of different modifications to the light 545 (i.e., similar to what is shown in FIG. 3B) in order to provide a plurality of views. In the embodiment illustrated in FIG. 5C, each of the meta-surfaces 540 provide light 545₁ at a first angle, light 545₂ at a second angle, and light 5453 at a third angle.

In an embodiment, the meta-surfaces 540 in the pixel 530 may provide the same angle (or angles) of light 545 emitted by all of the subpixels 532 within the pixel 530. Different pixels 530 may provide different angles (i.e., the meta-surface provides a desired angle of light 545 that depends on the location of the pixel 530 on the display backplane 518). While all meta-surfaces 540 within a given pixel may provide the same angle of emitted light 545, it is to be appreciated that the meta-surfaces 540 may not all be the same. Particularly, the angle of the emitted light 545 is partially dependent on the wavelength of the light. That is, for a given meta-surface 540, the angle of the emitted light 545 will be different for a green subpixel 532_{G}, a blue subpixel 532_{B}, and a red subpixel 532_{R}. Accordingly, the first meta-surface 540_{G} may be designed to steer light emitted by the first color subpixel 532_{G}, the second meta-surface 540E may be designed to steer light emitted by the second color subpixel 532_{B}, and the third meta-surface 5408 may be designed to steer light emitted by the third color subpixel 532_{R}.

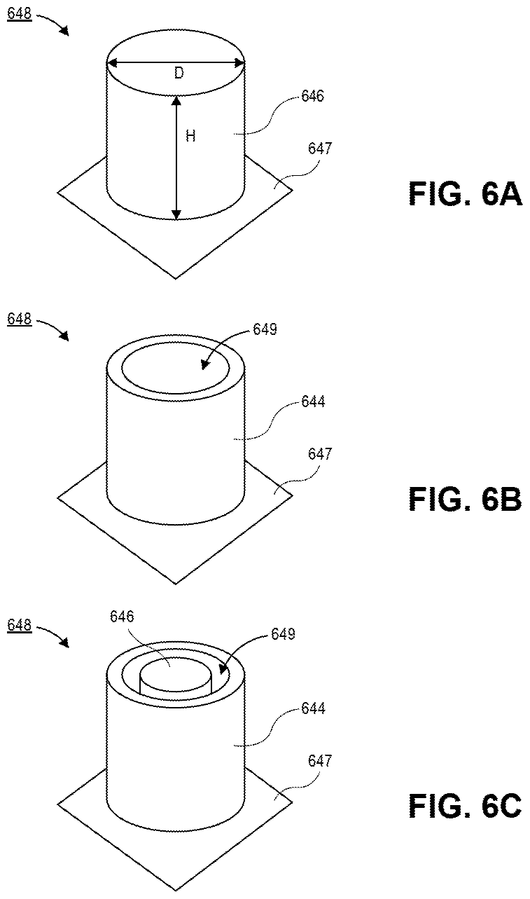

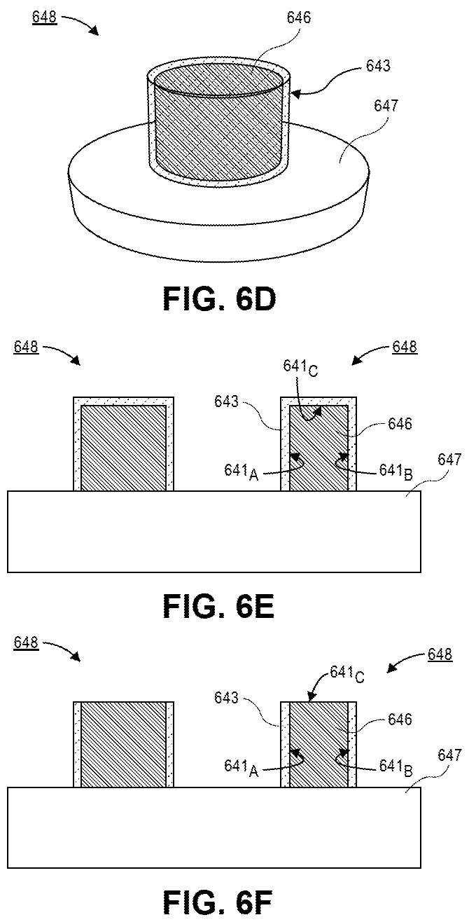

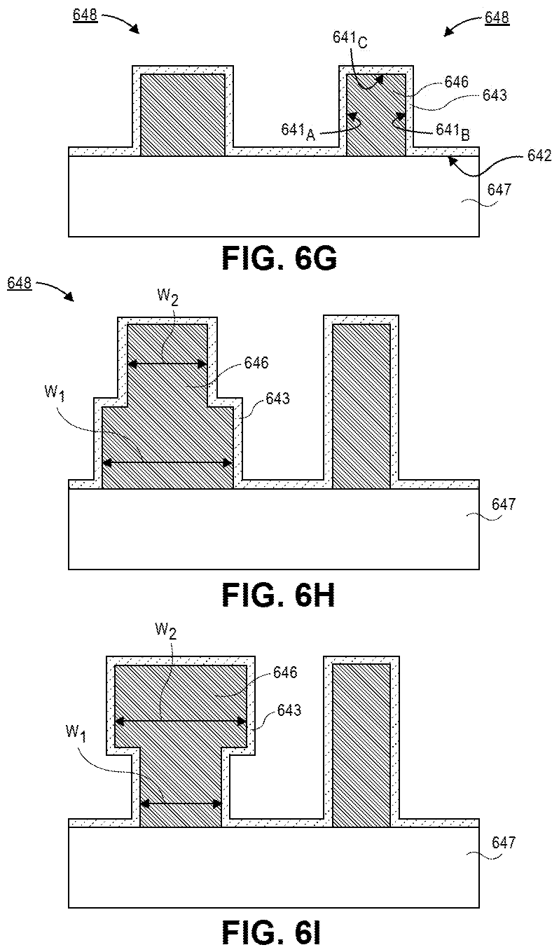

In an embodiment, the meta-surfaces 540 may be placed over the respective subpixels 532 with a transfer process. That is, the meta-surfaces 540 may be fabricated on one or more source substrates and subsequently transferred to the display backplane 518. For example, a meta-surface material layer (e.g., a transparent dielectric, such as TiO₂) may be deposited over a substrate. Features with a dimension less than the wavelength of the light emitted by the subpixel may then be patterned into the meta-surface material layer (e.g., with 193 nm immersion ArF laser steppers or nanoimprint lithography). Examples of features suitable to form meta-surfaces are described in greater detail below with respect to FIGS. 6A-6C.

The ability to steer the light emitted by the subpixels is provided by controlling the phase distribution of the light waves. In meta-surfaces such as those described herein, the required phase distribution is realized by controlling the size and distribution of nano-features of the meta-surface. In an embodiment, the meta-surface device may comprise an array of nano-features that are formed of a material that has a low loss for visible light (e.g., TiO₂, GaP, ZrTiO₄, HfTiO₄, or the like).

Referring now to FIGS. 6A-6C, cross-sectional illustrations of exemplary nano-features are shown, in accordance with embodiments. In FIG. 6A, the nano-feature 648 comprises a post 646 over a substrate 647. The post 646 may have a diameter D that is less than the wavelength of the light emitted by an underlying subpixel. The post 646 may have a height H that is approximately 300 nm or less. In FIG. 6B, the nano-feature 648 comprises a shell 644 formed over the substrate 647. The shell 644 may have an opening 649 formed through its center. In FIG. 6C, the nano-feature 648 comprises a shell 644 with a post 646 in the opening 649. A meta-surface with a plurality of different types of nano-features 648 provides improved flexibility in the design of the meta-surface since the different types of nano-features provide different phase dispersions. For example, nano-features 648 that comprises a pillar 646 are highly dispersive (i.e., the pillars cause larger phase delays for light with shorter wavelengths), and nano-features 648 that comprise a shell 644 are less dispersive.

In FIGS. 6A-6C, the nano-features 648 are all illustrated as monolithic features formed from a single material. However, it is to be appreciated that material limitations in such embodiments may not provide a desired light extraction efficiency. Such nano-features are typically formed with exceptionally high refractive index materials (e.g., greater than 3.0). For example, meta-surfaces for beam shaping have been developed for near-infrared light using high refractive index material such as silicon. These silicon-based meta-surface structures, however, absorb an undesirably large percentage of impinging light (e.g., 40% or more) in the visible range (e.g. red, green and blue). Visible wavelength transparent materials, such as silicon nitride (Si₃N₄) with a refractive index of about 2.0, have not been considered to have a sufficiently high refractive index to support the optical resonance desired to effectively manipulate optical wave-fronts. The use of titanium oxide (TiO₂) with refractive index of approximately 2.4-2.6 has been proposed for meta-surfaces operating with visible lights. However, the lower refractive index contrast compared to silicon of nanostructures formed with TiO₂ require very high aspect ratios (e.g., 5-10), which makes the fabrication very challenging. For example, the deposition of approximately 600 nm of TiO₂ using atomic layer deposition (ALD) is very expensive because of the small deposition rate of ALD process (e.g., approximately 0.05 nm/s).

It is generally believed that meta-surfaces require sufficiently large dielectric contrast relative to their background environment to enable the confinement and manipulation of light within nanoscale structures. For visible light, the highest index materials (Si or Ge) suffer from large optical loss due to small band gap (≤1.12 eV). Accordingly, embodiments disclosed herein include nano-features 648 that combine materials with high light confinement and low optical absorption in the visible range, while achieving high manufacturing throughput which is essential for low manufacturing cost. Examples of such nano-features are illustrated in FIGS. 6D-6I.

Referring now to FIG. 6D, a perspective view illustration of a nano-feature 648 with a core 646 and a coating 643 over a substrate 647 is shown in accordance with an embodiment. As shown, the nano-feature 648 may comprise a core material 646 that is covered by a coating 643. In an embodiment, the core 646 may be cylindrical, though other shaped cores 646 are possible. In an embodiment, the core 646 may be a material with relatively low refractive index. For example, the core 646 may be Si₃N₄. In an embodiment, the core 646 may be surrounded by an ultrathin coating material 643 with high refractive index. For example, the coating 643 may be TiO₂ or Si). The thin dimension of the coating 636 layer enables a small optical path to minimize optical loss. Furthermore, it is to be appreciated that such a nano-feature 648 improves manufacturability. For example, the deposition rate of the thick core 646 (e.g., Si₃N₄) may be much higher than that of the coating (e.g., TiO₂), enabling high throughput. The thin TiO₂ or Si “coating” may be deposited using ALD which provides excellent thickness control and the required conformality around the core.

Referring now to FIG. 6E, a cross-sectional illustration of a pair of nano-features 648 is shown, in accordance with an embodiment. In an embodiment, the nano-features 648 may comprise a core 646 with a coating 643 surrounding all exposed surfaces. For example, the coating 643 may be formed over the sidewalls 641A and 641B, and over the top surface 641c of the core 646. Due to the deposition with an ALD process, the thickness of the coating 643 may be uniform over all surfaces.

Referring now to FIG. 6F, a cross-sectional illustration of a pair of nano-features 648 is shown, in accordance with an additional embodiment. In an embodiment, nano-features 648 may be substantially similar to nano-features 648 in FIG. 6E, with the exception that the coating 643 is omitted from the top surface 641c of the core 646. In some embodiments, the coating 643 may be polished off of the top surface 641c. Additional embodiments may include masking the top surface 641c to prevent deposition if the coating 643.

Referring now to FIG. 6G, a cross-sectional illustration of a pair of nano-features 648 is shown, in accordance with an additional embodiment. In an embodiment, nano-features 648 may be substantially similar to nano-features 648 in FIG. 6E with the exception that the coating 643 is also formed over surface 642 of the substrate 647.

Referring now to FIGS. 6H and 61, cross-sectional illustrations of nano-features 648 are shown in accordance with additional embodiments. In FIGS. 6H and 61, one of the two nano-features 648 are shown as having non-uniform cross-sections. That is, a width of the core 646 may be non-uniform. For example, in FIG. 6H a first width W₁ towards the bottom of the core 646 may be greater than a second width W₂ towards the top of the core 646. In an alternative embodiment illustrated in FIG. 6I, the first width W₁ is less than the second width W₂. While embodiments show two distinct widths W₁ and W₂, it is to be appreciated that the core 346 may comprise any number of different widths (e.g., two or more). Additionally, the width may be continuously changing (e.g., sidewalls of the core 346 may be tapered, or the like.

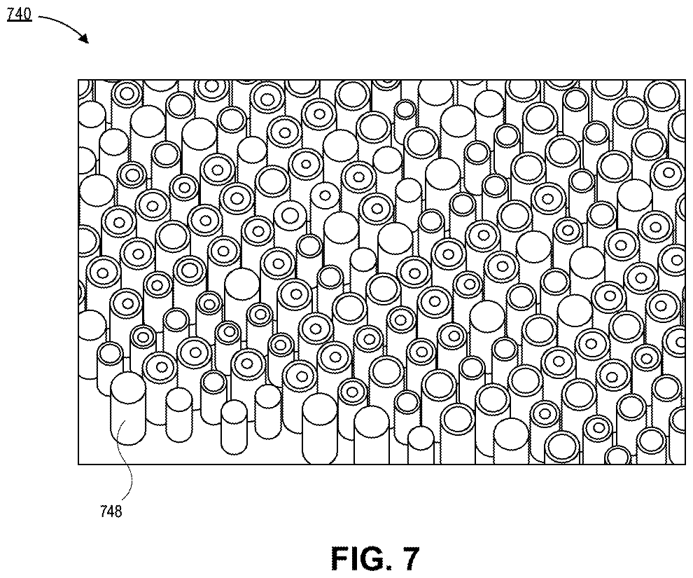

FIG. 7 provides an example of a meta-surface 740 with an array of nano-features 748, in accordance with an embodiment. In an embodiment, the positioning and type of nano-features 748 in the array is chosen to provide a desired modification to light emitted by an underlying subpixel. The nano-features 748 may have different diameters and be arranged in a lattice (e.g., a hexagonal lattice). Each of the nano-features 748 may be considered as a short waveguide with circular cross-section truncated on both sides—operating as a low-quality-factor Fabry-Perot resonator. The circular cross-section of the nano-features 748 allows for polarization insensitive operation. Due to the high index contrast between the nano-features 748 and the surrounding, the nano-features 748 behave as independent scatterers with small cross-coupling. The phase and amplitude of the scattered light depends on the diameter of the posts. The phase of the transmitted light, which is the sum of the incident and forward scattered light, can be controlled to take any value in the 0-2π range by properly selecting the post diameter. The local transmission coefficient of an array of nano-features 748 with gradually varying diameters can be approximated by the transmission coefficient of a uniform periodic array of nano-features 748. The subwavelength lattice constant and the large number of phase steps provided by the continuous post diameter-phase relation, enables accurate implementation of any phase profile optimized for a specific application. To design the proper array, an algorithm may be used to select the best nano-feature 748 from a library (e.g., a library including different nano-features 648, such as those shown in FIGS. 6A-6C) for each position on the meta-surface based on the required phase dispersion.

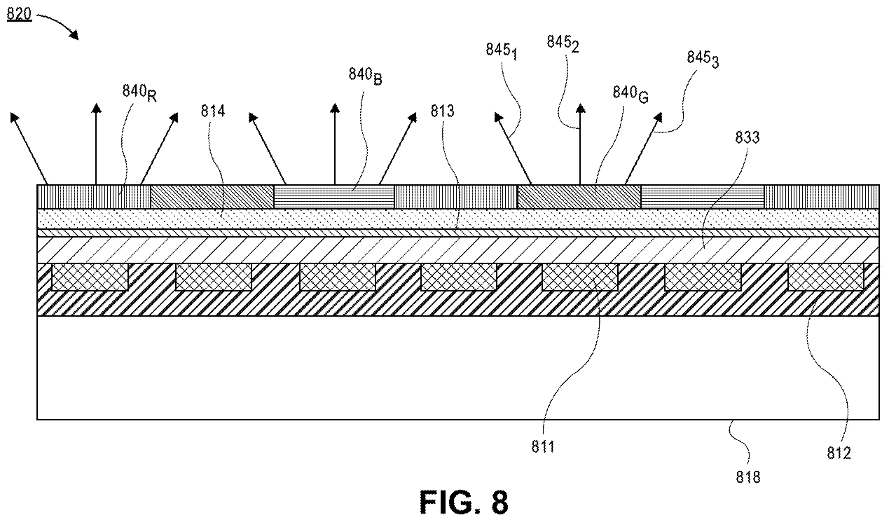

Referring now to FIG. 8, a cross-sectional illustration of a display 820 that includes meta-surfaces 840 that also function as color conversion devices is shown, in accordance with an additional embodiment. In an embodiment, the display 820 may include a display backplane 818. A plurality of anodes 811 may be formed in a dielectric layer 812. In an embodiment, a white OLED 833 may be formed over the anodes 811. A transparent cathode 813 may be formed over the white OLED 833. In an embodiment, a passivation layer 814 may be formed over the transparent cathode 813.

In an embodiment, a plurality of meta-surfaces 840 may be formed over the white OLED 833. Each meta-surface 840 may comprise nano-features that provide one or more views of light 845₁-845₃. Additionally, the meta-surfaces 840 may be color conversion devices. That is, the meta-surfaces 840 may change the white light emitted by the white OLED 833 to a colored light. For example, meta-surfaces 840_{R} may convert white light to red light, meta-surfaces 840_{B} may convert white light to blue light, and meta-surfaces 840_{G} may convert white light to green light. In an embodiment, the color conversion may be implemented with quantum dots, nanophosphors, or the like.

In the illustrated embodiment, color light (e.g., green, blue red) is obtained from a single white OLED 833 by three different color changing meta-surfaces 840_{G}, 840_{B}, 840_{R}. However, it is to be appreciated that embodiments may also include color changing devices for one or more of the colors in a pixel. For example, blue micro LEDs may be used as the source for each color, and red color changing meta-surfaces and green color changing meta-surfaces may be used to convert blue light to red light and green light. In some embodiments, only the meta-surface for red subpixels comprises a color changing device.

The use of meta-surfaces in combination with micro LEDs allows several advantages over other techniques. Placing a unique meta-surface above each subpixel enables independent control of the angle/view of each subpixel. This in combination with the variable pixel size enabled by using micro LEDs allows for unique opportunities for optimization. One optimization includes the trade off of luminance and chrominance resolution in terms of viewpoints. The eye is considerably less sensitive to red and blue light in the visible color space, so optimizing the resolution of green subpixels (i.e., luminance) relative to red and blue subpixels (i.e., chrominance) enables a higher resolution of perceived pixels. A display 920 that takes advantage of this tradeoff is shown in FIGS. 9A and 9B.

As shown in the plan view illustration in FIG. 9A, a display 920 may comprise a plurality of pixels 930 on a display backplane 918. Each pixel may comprise a plurality of sub-pixels (e.g., blue subpixels 932_{B}, red subpixels 932_{R}, and green subpixels 932G). In an embodiment, the number of green subpixels 932G may be greater than the number of blue subpixels 932_{B} or red subpixels 932_{R}. For example, there may be nine green subpixels 932G for every one blue subpixel 932_{B} or red subpixel 932_{R}.

Referring now to FIG. 9B, a cross-sectional view illustrates the light 945 from the subpixels. As shown, each green subpixel 932G may have a unique path for the light 945₁, 945₂, or 945₃. The same number of views may be spread over each individual blue subpixel 932_{B} or red subpixel 932_{R}. By implementing different optical functions over the individual pixels, the energy from the red subpixels 932_{R} and blue subpixels 932_{B} may be spread over multiple viewpoints. This may reduce the number of pixels required for a given spatial and angular resolution by up to 50%.

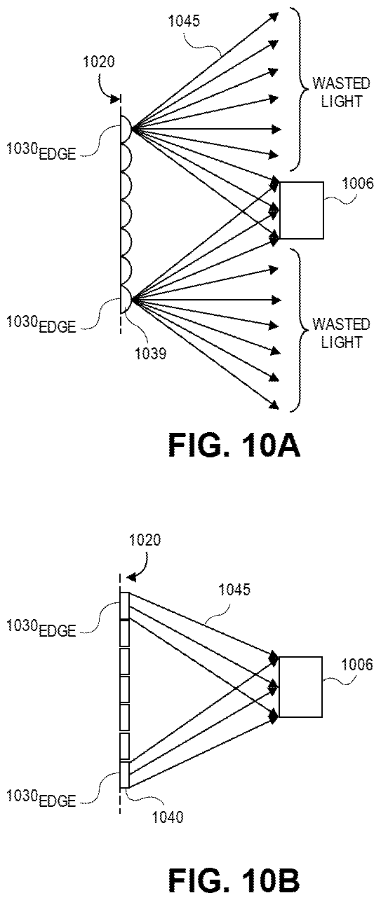

A second non-uniform optimization is illustrated in FIGS. 10A and 10B. In cases where the parallax views which need to be supported across the display is significant—which is common in far eye displays or any display with a large field of view and a fixed view point—generating a wide field of viewpoints with a lens array for each set of elemental images under a lens leads to many viewpoints being generated that are not in fact visible to the user.

For example, in the schematic of a display 1020 with a lens based array, pixels 1030_{Edge} near the edge of the display may have a significant portion of the light 1045 directed outside of the eye-box 1006 by the lenses 1039. In contrast, FIG. 10B provides a schematic of a display 1020 with a meta-surfaces based array. The meta-surfaces 1040 allow for all of the light 1045 emitted by the edge pixels 1030_{Edge} to be directed to the eye-box 1006. Focusing the viewpoints of light 1045 into the eye-box 1006 further improves the spatial versus angular trade off. Placing unique meta-surfaces on each subpixel enables even the edge pixels 1030_{Edge} to contribute to the resolution in the target eye-box, and improvements to the perceived spatial or angular resolution are obtained.

In yet another embodiment, adaptive subpixel resolution may be obtained with a pupil tracing device in order to increase the resolution in the foveae region of the eye. For example, some of the green subpixels of pixel (e.g., some of the plurality of green subpixels 932G in FIG. 9A) may be reserved for foveated rendering when the eye is known to be in the zone for that view. As such, more luminance and color information can be delivered to the color sensitive cones in the foveae. The computational requirements on the GPU for such a display would not be significant because only a small portion of the display is viewed in the foveated region at a given time.

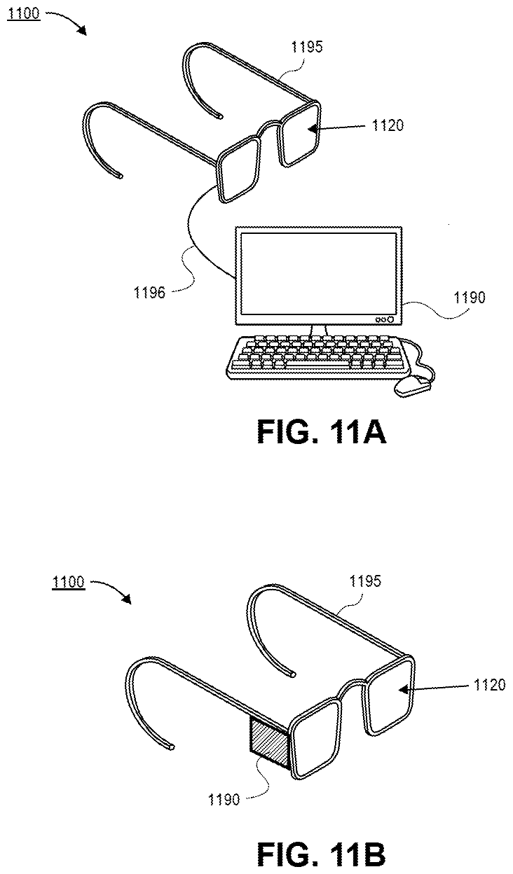

Referring now to FIGS. 11A and 11B, schematics of a head mounted display 1100 are shown, in accordance with embodiments. In FIG. 11A, the head mounted display 1100 comprises a display 1120 attached to a frame 1195. The display 1120 may be any suitable display, such as those described above that include meta-surfaces over subpixels. In the illustrated embodiment, the frame 1195 resembles the frames of glasses, with the display 1120 being positioned where the lenses normally are positioned. However, it is to be appreciated that other frame/display configurations are possible in accordance with various embodiments. In an embodiment, a computer 1190 may be attached to the display 1120 with a cable 1196. The computer 1190 may provide the processing power (e.g., for graphics rendering, etc.) for the display 1120. In an additional embodiment, the computer 1190 may be integrated with the frame 1195, as shown in FIG. 11B. In such an embodiment, the head mounted display 1100 may be considered a wireless or untethered display.

While FIGS. 11A and 11B illustrate a head mounted display 1100, it is to be appreciated that embodiments such as those described herein are capable of being integrated into any display technology. For example, 3D displays with meta-surfaces such as those described herein may be used in displays with form-factors for use in mobile devices (e.g., cell phones, tablets, laptop computers, etc.) or in larger form factors (e.g., televisions, computer displays, etc.).

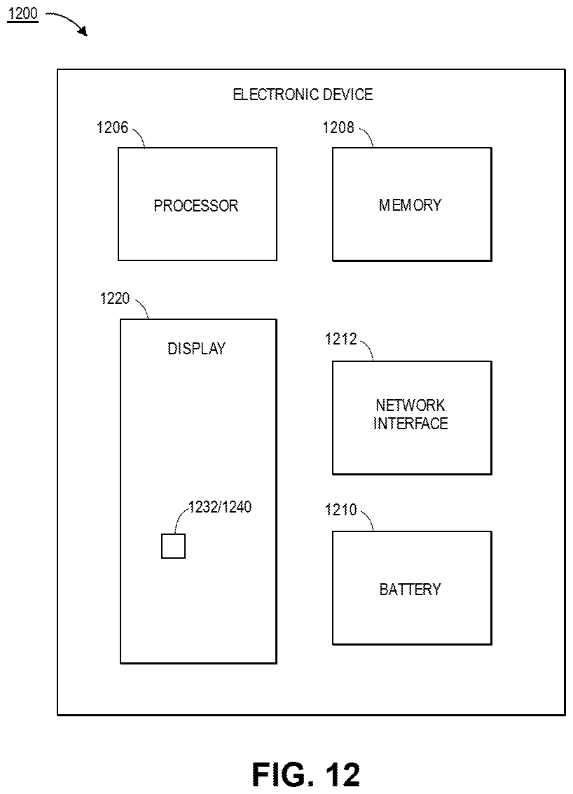

FIG. 12 is an electronic device having a display, in accordance with embodiments of the present disclosure. Referring to FIG. 12, an electronic device 1200 has a display or display panel 1220 with a subpixel/meta-surface 1232/1240 combination. The display may also have glass layers and other layers, circuitry, and so forth. The display panel 1220 may be a micro-LED display panel. As should be apparent, only one subpixel/meta-surface 1232/1240 is depicted for clarity, though a display panel 1220 will have an array or arrays of subpixel/meta-surface 1232/1240 combinations.

The electronic device 1200 may be a mobile device such as smartphone, tablet, notebook, smartwatch, and so forth. The electronic device 1200 may be a computing device, stand-alone display, television, display monitor, vehicle computer display, the like. Indeed, the electronic device 1200 may generally be any electronic device having a display or display panel.

The electronic device 1200 may include a processor 1206 (e.g., a central processing unit or CPU) and memory 1208. The memory 1208 may include volatile memory and nonvolatile memory. The processor 1206 or other controller, along with executable code store in the memory 1208, may provide for touchscreen control of the display and well as for other features and actions of the electronic device 1200.

In addition, the electronic device 1200 may include a battery 1210 that powers the electronic device including the display panel 1202. The device 1200 may also include a network interface 1212 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 1200 may include additional components including circuitry and other components.

Thus, embodiments described herein include micro light-emitting diode (LED) fabrication and assembly.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a display, comprising: a display backplane substrate; a light emission source on the display backplane substrate; and a meta-surface over the light emission source, wherein the meta-surface comprises a plurality of nano-features for modifying a path of light emitted by the light emission source.

Example 2: the display of Example 1, wherein the meta-surface is separated from the light emission source by a dielectric layer.

Example 3: the display of Example 1 or Example 2, wherein the meta-surface comprises TiO₂.

Example 4: the display of Examples 1-3, light emission source is a micro light emitting diode (LED).

Example 5: the display of Examples 1-4, wherein the micro LED emits white light, and wherein the meta-surface further comprises a color changing device that converts the white light to red light, blue light, or green light.

Example 6: the display of Examples 1-5, wherein the meta-surface comprises a plurality of regions, wherein each region provides a different modification of the path of light emitted by the emission source.

Example 7: the display of Examples 1-6, wherein the nano-features comprise one or more of a post, a shell, or a post surrounded by a shell.

Example 8: the display of Examples 1-7, wherein a dimension of the nano-features is less than the wavelength of the light emitted by the light emission source.

Example 9: the display of Examples 1-8, wherein the nano-features comprise a core and a coating surrounding the core.

Example 10: the display of Examples 1-9, wherein the coating surrounds sidewall surfaces of the core, or the coating surrounds sidewall surfaces and a top surface of the core.

Example 11: the display of Examples 1-10, wherein the core has a non-uniform width.

Example 12: the display of Examples 1-11, wherein the core is Si₃N₄ and the coating is Si or TiO₂.

Example 13: a three-dimensional (3D) display, comprising: a display backplane substrate; and a plurality of pixels on the display backplane substrate, wherein each of the pixels comprises: a first subpixel, wherein a first meta-surface is positioned over the first subpixel, the first meta-surface having a plurality of nano-features for modifying a path of light emitted by the first subpixel; a second subpixel, wherein a second meta-surface is positioned over the second subpixel, the second meta-surface having a plurality of nano-features for modifying a path of light emitted by the second subpixel; and a third subpixel, wherein a third meta-surface is positioned over the third subpixel, the third meta-surface having a plurality of nano-features for modifying a path of light emitted by the third subpixel.

Example 14: the 3D display of Example 13, wherein the first subpixel emits green light, the second subpixel emits red light, and the third subpixel emits blue light.

Example 15: the 3D display of Example 13 or Example 14, wherein the first meta-surface modifies light emitted by the first subpixel by a first angle, the second meta-surface modifies light emitted by the second subpixel by a second angle, and the third meta-surface modifies light emitted by the third subpixel by a third angle.

Example 16: the 3D display of Examples 13-15, wherein, within each pixel, the first angle, the second angle, and the third angle of each pixel are equal to each other.

Example 17: the 3D display of Examples 13-16, wherein the each of the first meta-surface, the second meta-surface, and the third meta-surface comprise a plurality of regions, wherein each region provides a different modification of the path of light emitted by the respective subpixels.

Example 18: the 3D display of Examples 13-17, wherein the first subpixel is a blue subpixel, the second subpixel is a red subpixel, and the third subpixel is a green subpixel.

Example 19: the 3D display of Examples 13-18, wherein each pixel comprises a plurality of third subpixels.

Example 20: the 3D display of Examples 13-19, wherein each first meta-surface comprises a plurality of regions, wherein each region provides a different modification of the path of light emitted by the respective subpixel, and wherein each second meta surface comprises a plurality of regions, wherein each region provides a different modification of the path of light emitted by the respective subpixel.

Example 21: the 3D display of Examples 13-20, wherein the subpixels comprise micro light emitting diodes (LEDs).

Example 22: the 3D display of Examples 13-21, wherein the meta-surfaces comprise TiO₂.

Example 23: a head mounted three-dimensional (3D) display, comprising: a frame, wherein the frame is supporting the 3D display on a user's head; a display mechanically coupled to the frame, wherein the display provides a multi-view light field to each eye of the user; and a computing device communicatively coupled to the display.

Example 24: the head mounted 3D display of Example 23, wherein the display comprises: a display backplane substrate; and a plurality of pixels on the display backplane substrate, wherein each of the pixels comprises: a first subpixel, wherein a first meta-surface is positioned over the first subpixel, the first meta-surface having a plurality of nano-features for modifying a path of light emitted by the first subpixel; a second subpixel, wherein a second meta-surface is positioned over the second subpixel, the second meta-surface having a plurality of nano-features for modifying a path of light emitted by the second subpixel; and a third subpixel, wherein a third meta-surface is positioned over the third subpixel, the third meta-surface having a plurality of nano-features for modifying a path of light emitted by the third subpixel.

Example 25: the head mounted 3D display of Example 23 or Example 24, wherein each of the first meta-surface, the second meta-surface, and the third meta-surface comprise a plurality of regions, wherein each region provides a different modification of the path of light emitted by the respective subpixels in order to generate the multi-view light field.

What is claimed is:

1. A display, comprising:
a display backplane substrate;
a light emission source on the display backplane substrate; and
a meta-surface over the light emission source, wherein the meta-surface comprises a plurality of nano-features for modifying a path of light emitted by the light emission source.

2. The display of claim 1, wherein the meta-surface is separated from the light emission source by a dielectric layer.

3. The display of claim 1, wherein the meta-surface comprises TiO₂.

4. The display of claim 1, light emission source is a micro light emitting diode (LED).

5. The display of claim 4, wherein the micro LED emits white light, and wherein the meta-surface further comprises a color changing device that converts the white light to red light, blue light, or green light.

6. The display of claim 1, wherein the meta-surface comprises a plurality of regions, wherein each region provides a different modification of the path of light emitted by the emission source.

7. The display of claim 1, wherein the nano-features comprise one or more of a post, a shell, or a post surrounded by a shell.

8. The display of claim 7, wherein a dimension of the nano-features is less than the wavelength of the light emitted by the light emission source.

9. The display of claim 1, wherein the nano-features comprise a core and a coating surrounding the core.

10. The display of claim 9, wherein the coating surrounds sidewall surfaces of the core, or the coating surrounds sidewall surfaces and a top surface of the core.

11. The display of claim 9, wherein the core has a non-uniform width.

12. The display of claim 9, wherein the core is Si₃N₄ and the coating is Si or TiO₂.

13. A three-dimensional (3D) display, comprising:
a display backplane substrate; and
a plurality of pixels on the display backplane substrate, wherein each of the pixels comprises:
a first subpixel, wherein a first meta-surface is positioned over the first subpixel, the first meta-surface having a plurality of nano-features for modifying a path of light emitted by the first subpixel;
a second subpixel, wherein a second meta-surface is positioned over the second subpixel, the second meta-surface having a plurality of nano-features for modifying a path of light emitted by the second subpixel; and
a third subpixel, wherein a third meta-surface is positioned over the third subpixel, the third meta-surface having a plurality of nano-features for modifying a path of light emitted by the third subpixel.

14. The 3D display of claim 13, wherein the first subpixel emits green light, the second subpixel emits red light, and the third subpixel emits blue light.

15. The 3D display of claim 14, wherein the first meta-surface modifies light emitted by the first subpixel by a first angle, the second meta-surface modifies light emitted by the second subpixel by a second angle, and the third meta-surface modifies light emitted by the third subpixel by a third angle.

16. The 3D display of claim 15, wherein, within each pixel, the first angle, the second angle, and the third angle of each pixel are equal to each other.

17. The 3D display of claim 13, wherein the each of the first meta-surface, the second meta-surface, and the third meta-surface comprise a plurality of regions, wherein each region provides a different modification of the path of light emitted by the respective subpixels.

18. The 3D display of claim 13, wherein the first subpixel is a blue subpixel, the second subpixel is a red subpixel, and the third subpixel is a green subpixel.

19. The 3D display of claim 18, wherein each pixel comprises a plurality of third subpixels.

20. The 3D display of claim 19, wherein each first meta-surface comprises a plurality of regions, wherein each region provides a different modification of the path of light emitted by the respective subpixel, and wherein each second meta surface comprises a plurality of regions, wherein each region provides a different modification of the path of light emitted by the respective subpixel.

21. The 3D display of claim 13, wherein the subpixels comprise micro light emitting diodes (LEDs).

22. The 3D display of claim 13, wherein the meta-surfaces comprise TiO₂.

23. A head mounted three-dimensional (3D) display, comprising:
a frame, wherein the frame is supporting the 3D display on a user's head;
a display mechanically coupled to the frame, wherein the display provides a multi-view light field to each eye of the user; and
a computing device communicatively coupled to the display.

24. The head mounted 3D display of claim 23, wherein the display comprises:
a display backplane substrate; and
a plurality of pixels on the display backplane substrate, wherein each of the pixels comprises:
a first subpixel, wherein a first meta-surface is positioned over the first subpixel, the first meta-surface having a plurality of nano-features for modifying a path of light emitted by the first subpixel;
a second subpixel, wherein a second meta-surface is positioned over the second subpixel, the second meta-surface having a plurality of nano-features for modifying a path of light emitted by the second subpixel; and
a third subpixel, wherein a third meta-surface is positioned over the third subpixel, the third meta-surface having a plurality of nano-features for modifying a path of light emitted by the third subpixel.

25. The head mounted 3D display of claim 24, wherein each of the first meta-surface, the second meta-surface, and the third meta-surface comprise a plurality of regions, wherein each region provides a different modification of the path of light emitted by the respective subpixels in order to generate the multi-view light field.
